(19) United States
(12) Patent Application Publication
(10) Pub. No.: US 2026/0305319 A1
(43) Pub. Date: Oct. 1, 2026

(54) HIGH-DENSITY CAPACITOR STRUCTURES IN ICs WITH BACKSIDE METALLIZATION

(71) Applicant: Intel Corporation, Santa Clara, CA (US)

(72) Inventors: Tuhin Guha Neogi, Beaverton, OR (US); Denzil Frost, Rio Rancho, NM (US); Chia-Ching Lin, Portland, OR (US); Uygar Avci, Portland, OR (US)

(73) Assignee: Intel Corporation, Santa Clara, CA (US)

(21) Appl. No.: 19/093,981

(22) Filed: Mar. 28, 2025

(51) Int. Cl. H01L 23/522

(52) U.S. Cl. CPC H10W 20/496

(57) ABSTRACT

Integrated circuit (IC) die with a high-density capacitor structure electrically coupled to power rails routed with interconnect metallization that is on a backside of the IC. The capacitor structure may have a serpentine of staircase structure, for example offering greater capacitor surface area for a given footprint of the IC die or enabling a MIM stack to have a greater number of continuous metal and insulator layers within a given footprint of the IC die.

### BACKGROUND

For advanced integrated circuits (ICs), the introduction of back-side interconnect metallization, for example to supply power to transistors, counters the trend of increasing electrical resistance associated with dimensional scaling of frontside interconnect metallization.

The integration of de-coupling capacitors within an IC die can reduce ground bounce during operation of high-performance integrated circuits sensitive to such transients. IC architectures enabling the integration of more and/or larger capacitors may be advantageous for some applications. Higher density capacitor architectures embedded within front-side or back-side interconnect metallization are therefore commercially advantageous.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating methods of fabricating IC devices including high-density capacitor structures coupled with backside interconnect metallization, in accordance with some embodiments;

FIGS. 2, 3A and 3B are cross-sectional views of an IC die structure comprising a high-density capacitor structure embedded within backside interconnect metallization of an IC die structure, in accordance with some embodiments;

FIGS. 4A, 4B, 4C and 4D are cross-sectional views of a high-density capacitor structure evolving as the methods illustrated in FIG. 1 are practiced, in accordance with some embodiments;

FIG. 5 is a cross-sectional view of a high-density capacitor structure, in accordance with some further embodiments;

FIGS. 6A, 6B and 6C are cross-sectional views of a high-density capacitor structure evolving as the methods illustrated in FIG. 1 are practiced, in accordance with some alternative embodiments;

FIG. 7 is a cross-sectional view illustrating a microelectronic device assembly including an embedded high-density capacitor structure; in accordance with some embodiments;

FIG. 8 illustrates a mobile computing platform and a data server machine employing an IC device including an embedded high-density capacitor structure, in accordance with some embodiments; and

FIG. 9 is a functional block diagram of an electronic computing device, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. In one example, two compositions that are substantially the same, have only incidental chemical variation. As another example, composition that is substantially a first constituent means the composition may further include <1% of any other constituent. A composition that is substantially first and second constituents means the composition may further include <1% of any constituent substituted for either the first or second constituent.

In accordance with embodiments herein, high-density capacitor structures are embedded within backside interconnect metallization levels and electrically coupled to power rails routed with backside interconnect metallization. The high-density structures may include topographic features that increase total area and/or enable an increase in the number of plates of a capacitor occupying a given footprint of an IC device. The high-density structures described herein may offer greater electrical charge capacitance through the introduction of lateral recesses along a vertical depth spanned by plates of the structures. The high-density capacitor structures described herein may be fabricated subsequent to fabrication of transistor structures within a device layer, for example during the fabrication of backside interconnect levels of an IC die structure.

In accordance with some embodiments, a first plate of a high-density capacitor coupled to a first power supply rail (e.g., V_{dd}) is spaced from a second plate coupled to a second power supply rail (e.g., Vₛₛ) with an electrical insulator therebetween. Both capacitor plates may fold back on themselves two or more times in a serpentine profile to increase a lateral run length along a vertical depth spanned by the plates. In some further embodiments, one or more of the plates may comprise two or more layers of metal that follow the serpentine path. In accordance with some alternative embodiments, plates of a high-density capacitor follow a staircase profile over underlying dielectric material. Either of these embodiments may be implemented within trench or cylindrical via structures, for example as dependent on the polygonal shape of a via or trench that is etched into a dielectric material.

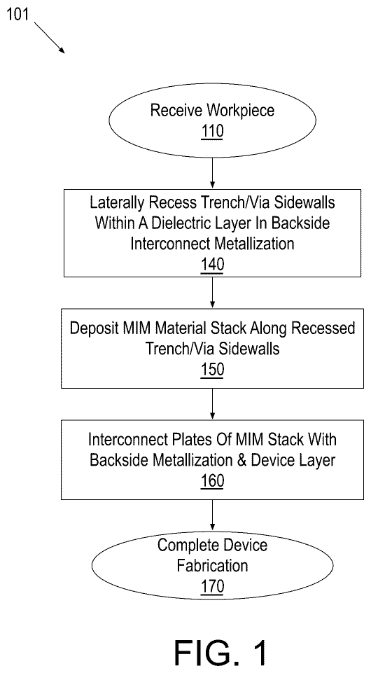

FIG. 1 is a flow diagram illustrating methods 101 for fabricating an IC die, chip, or chiplet with high-density capacitor structures coupled to backside interconnect metallization, in accordance with some exemplary embodiments. In some examples, methods 101 are performed on a 250-450 mm diameter wafer.

Methods 101 begin at input 110 with receipt of a workpiece that already includes a device layer or is suitable for the fabrication of a device layer. The device layer may comprise field effect transistor (FET) structures, or other integrated electrical and/or optical (photonic) device structures. The workpiece may further comprise frontside interconnect metallization levels over a front side of the device layer. In exemplary embodiments, a backside interconnect metallization structure id also fabricated over a back side of the device layer with methods 101 continuing at block 140 where sidewalls of a trench or via formed within a dielectric material layer of the backside interconnect metallization structure are laterally recessed with an etch process to increase surface area of the trench or via. Any isotropic etch process known to be suitable for the composition of the dielectric material may be practiced at block 140.

At block 150, a metal-insulator-metal (MIM) material stack comprising metal layers and at least one insulator layer is deposited into the trench or via that was expanded at block 140 with the lateral recess etch. Any film deposition processes known to be suitable for forming highly conformal metal films and insulator films may be practiced at block 150. In some examples, a chemical layer deposition (CVD) process or a cyclical atomic layer deposition (ALD) process is practiced to form each metal layer. In other examples, an electroplating process is practiced to form each metal layer. In further embodiments, a CVD process or a cyclical ALD process is practiced to form each insulator layer.

Methods 101 continue at block 160 where capacitor plates comprising separate metal layers of the MIM stack are electrically interconnected with backside interconnect metallization to the device layer (or frontside interconnect metallization) according to any known techniques. Methods 101 then end at output 170 with the completion of IC die fabrication. The IC die may then be singulated from the workpiece, and packaged according to any known techniques. The packaged IC die may then be assembled into a computer system or platform, such as a mobile device or data server platform, for example as described further below.

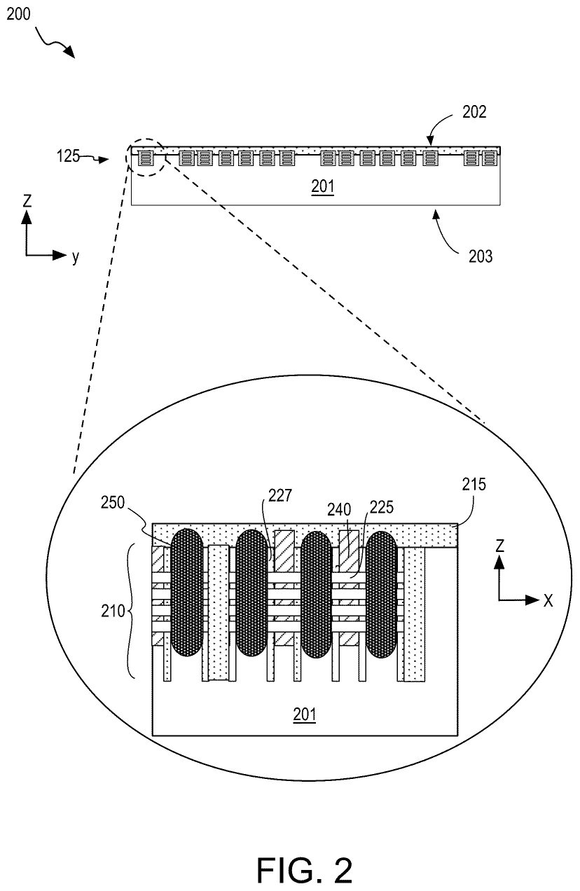

FIG. 2 is a cross-sectional view of an exemplary IC die structure 200 including a device layer 125 on a substrate material 201. In some embodiments, substrate material 201 is monocrystalline material, such as monocrystalline silicon, monocrystalline germanium, a monocrystalline silicon-germanium alloy, or a monocrystalline III-V material. One or more device material layers may be over substrate material 201. In the example further illustrated in expanded view of FIG. 2, a dielectric material layer 215 is over a front side 202 of substrate material 201, opposite back side 203. Dielectric material 215 may have any composition known to be suitable, such as silicon oxides (e.g., SiO₂), silicon nitrides (e.g., Si₃N₄), a silicon oxynitride, (SiON), or a low-k material having a relative permittivity below that of SiO₂, such as SiOCH. Although only one dielectric material layer is illustrated in FIG. 2, dielectric material 215 may comprise two or more material layers having a total thickness, for example in the range of 20-60 nm.

As further illustrated in the expanded view of FIG. 2, device layer 125 comprises transistor structures 210. In the illustrated nanosheet architecture example, transistor structures 210 comprises vertical stacks of channel material 225. Transistor channel material 225 may be associated with N-type (NMOS) transistor structures and/or P-type (PMOS) transistor structures, of for complementary FETs (CFETS), some channels of one stack may be associated with an NMOS transistor while other channels of one stack may be associated with a PMOS transistor. Notably, transistor structures 210 may also comprise less complex architectures such as a single finFET channel device, a planar channeled device, etc.

Regardless of the transistor architecture, channel material 225 may have any composition suitable for a channel of a field effect transistor (FET) and advantageously has a composition similar to, or substantially the same as, the composition of substrate material 201. In some examples where substrate material 201 is monocrystalline silicon, channel material 225 is also substantially pure silicon. However, in other embodiments where substrate material 201 is monocrystalline silicon, channel material 225 comprises germanium (e.g., SiₓGe_{1-X}, GeₓSn_{1-X}, or substantially pure Ge). In some other embodiments, channel material 225 includes a transition metal and a chalcogen. The transition metal may be any transition metal such as any element of groups 4 through 11, the group 3 elements scandium and yttrium, and the inner transition metals (e.g., f-block lanthanide and actinide series). Notable transition metals are molybdenum and tungsten. The chalcogen may be sulfur, selenium, and tellurium. In still other embodiments, channel material 225 comprises one or more metals and oxygen (i.e., metal oxide semiconductor), such as, but not limited to, Indium, gallium zinc oxide (IGZO).

Channel material 225 is advantageously crystalline. Although the crystalline semiconductor includes polycrystalline thin film material, in some embodiments channel material 225 is substantially monocrystalline. In some embodiments where channel material 225 is substantially pure silicon, the crystallinity of channel material 225 is cubic with a top surface having a crystallographic orientation of (100), (111), or (110). However, other crystallographic orientations are also possible. In other embodiments, channel material 225 may be polycrystalline or amorphous, for example in certain metal chalcogen and/or metal oxide embodiments.

Transistor structures 210 further include dielectric sidewall spacer dielectric material 227 surrounds underlying channel material 225. Sidewall spacer dielectric material 227 may comprise a silicon-based dielectric (e.g., SiO₂, Si₃N₄, SiON, etc.). Transistor structures 210 further include source and drain semiconductor material 250. PMOS and NMOS source and drain semiconductor material 250 may be separately grown, for example. In some PMOS transistor embodiments, source and drain semiconductor material 250 is a Si₁₋ₓGeₓ alloy further including acceptor impurities imparting p-type electrical conductivity. In some NMOS transistor embodiments, source and drain semiconductor material 250 is substantially pure silicon (i.e., only Group IV element is silicon) further including donor impurities imparting n-type electrical conductivity. Accordingly, except for the greater impurity concentration, source and drain semiconductor material 250 may have substantially the same chemical composition as substrate (semiconductor) material 201. Gate material 240 is adjacent to at least a sidewall of channel material 225 and may further wrap substantially around a nanowire or nanoribbon of channel material 225. Although not illustrated, gate material 240 is electrically coupled to channel material 225 through one or more layers of gate insulator material, which may be any high-k gate dielectric such as HfO₂, Al₂O₃, for example.

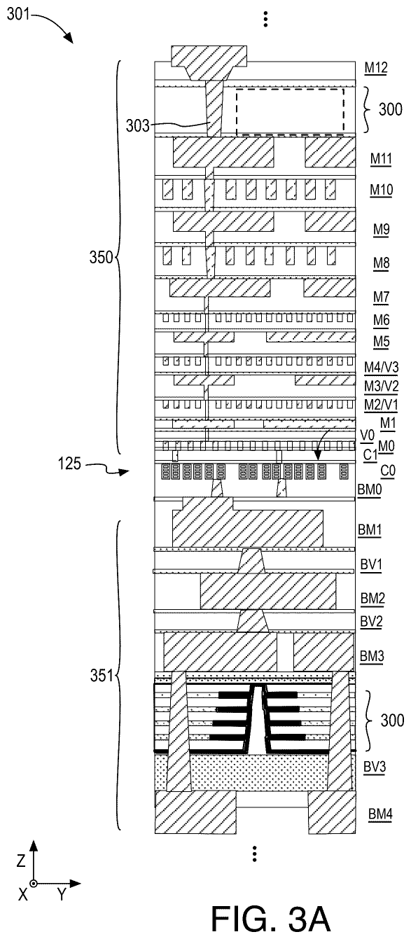

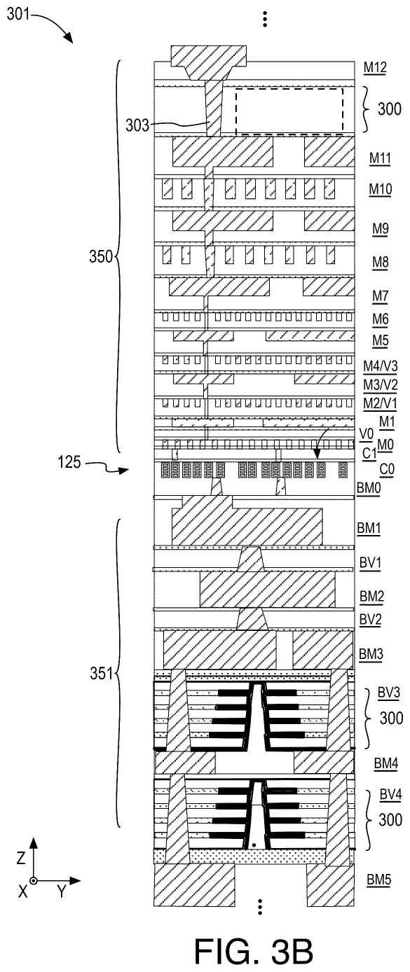

FIG. 3A further illustrates a cross-sectional view of an IC die structure 301 comprising device layer 125 between frontside interconnect metallization 350 and backside interconnect metallization 351. A high-density capacitor structure 300 in accordance with embodiments herein is embedded within backside interconnect metallization 351. In the illustrated example, high-density capacitor structure 300 is embedded within one or more layers of dielectric material between backside metal 3 (BM3) and backside metal 4 (i.e., coplanar with backside via 3, or BV3). In other embodiments, high-density capacitor structure 300 may be similarly embedded between other backside metallization levels or within frontside interconnect metallization 350, for example within a frontside via level 303 (e.g., V11), as denoted by a dashed-line box.

Frontside interconnect metallization 350 and backside interconnect metallization 351 may each comprise any number of metallization levels within any thickness of dielectric material. Frontside and backside interconnect metallization may be fabricated according to any known techniques (e.g., single or dual damascene, etc.), as embodiments herein are not limited in this respect. In some embodiments, some frontside metallization features are electrically coupled to at least drain semiconductor material of transistor structures 210 within device layer 125 while other frontside metallization features may be coupled to gate electrode material 240. In further embodiments, some backside metallization features are electrically coupled to at least some source semiconductor material of transistor structures 210 within device layer 125. As further illustrated, backside metallization features (e.g., within BM3) are electrically coupled to conductive plates of high-density capacitor structure 300. In some embodiments where one capacitor plate interconnect is to be powered from a host at a first power supply voltage (e.g., V_{dd}), another capacitor plate interconnect is powered from the host at a second power supply voltage (e.g., Vₛₛ). Power applied across these circuit nodes may therefore be conditioned to removed small transients (e.g., ripple or ground bounce) that would otherwise be passed into the transistor structures.

The high-density capacitor structure 300 illustrated in FIG. 3A may be arrayed over an area of an IC die, for example within one layer of the backside interconnect structure (e.g., BV3). Such an array of multiple capacitor structures may be electrically interconnected to each other thereby increasing total effective electrical capacitance, as needed for a given application. High-density capacitor structure 300 may also be arrayed over multiple layers of an interconnect structure. In FIG. 3B, for example, one or more first high-density capacitor structures 300 may be fabricated in one interconnect structure level (e.g., BV3) under one or more second high-density capacitor structures 300 fabricated in another interconnect structure level (e.g., BV4).

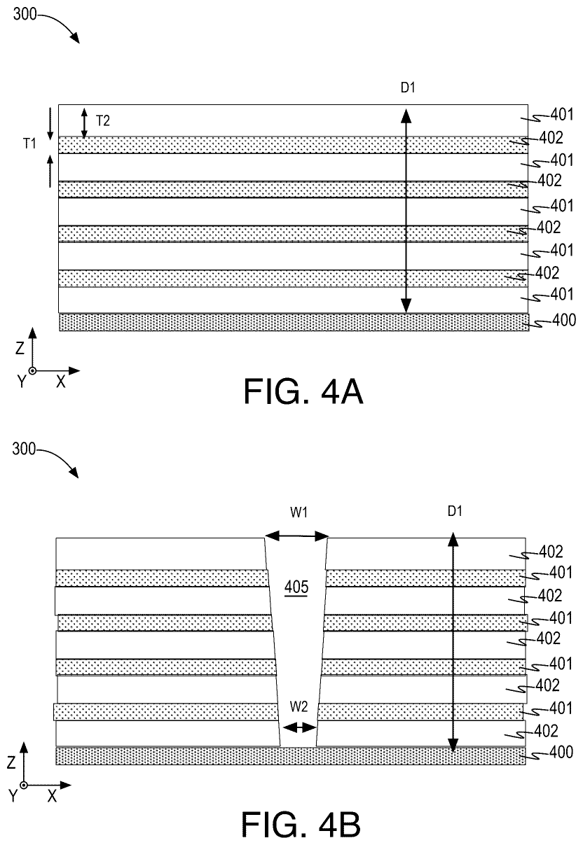

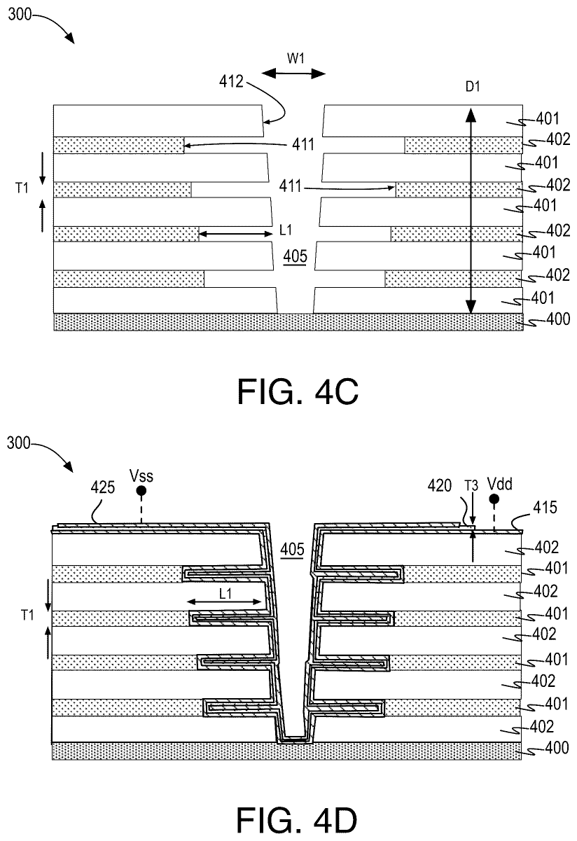

FIG. 4A-4D are cross-sectional views of high-density capacitor structure 300 evolving as the methods 101 are practiced, in accordance with some embodiments. Referring first to FIG. 4A, capacitor structure 300 comprises a bi-layer material stack of thickness, or depth, D1. Although depth D1 may vary with implementation, in some examples depth D1 is at least 500 nm and may be 600-750 nm, or more. The bi-layer material stack is over a base layer 400, which may be a metal or dielectric of any composition. Each bi-layer includes a first dielectric material layer 401 and a second dielectric material layer 402. Although four bi-layers are illustrated, a bi-layer stack may have any number of bi-layers (e.g., 2-20).

The chemical composition of dielectric material layer 401 is sufficiently different from the chemical composition of dielectric material layer 402 that one of dielectric material layer 401 or 402 may be etched selectively to the other of dielectric material layers 401 or 402. In some examples, both of dielectric material layers 401 and 402 comprise silicon (i.e., silicon-based). In some further examples, one of dielectric material layer 401 or 402 comprises more nitrogen than the other of dielectric material layer 401 or 402. In some embodiments, dielectric material layer 401 is silicon dioxide (SiO₂) while dielectric material layer 402 is silicon nitride (Si₃N₄) or silicon oxynitride (SiOₓN_{y}). Dielectric material layers 401 and 402 may have any thickness T1, T2, respectively. In some embodiments, thickness T1 is significantly greater than thickness T2. In other embodiments, thickness T1 is substantially the same as thickness T2. Although thicknesses T1 and T2 may vary with implementation, in some embodiments, at least one of thickness T1, T2 is less than 100 nm and advantageously less than 50 nm (e.g., 10-40 nm). In some further embodiments, both of thickness T1, T2 are less than 100 nm.

FIG. 4B further illustrates the formation of a trench or via 405 that extends through depth D1 and exposes base layer 400. Trench or via 405 may have any lateral dimensions. However, in trench embodiments, the lateral length (e.g., along y-axis) is at least five times larger than a largest lateral width W1 (e.g., along x-axis). In some trench examples, the lateral length is at least 150 nm. For via embodiments, the lateral length is substantially equal to the lateral width W1, which may vary with implementation. In some embodiments, depth D1 is at least five times lateral width W1, and may be 10-20 times lateral width W1. Accordingly, in some embodiments where depth D1 is more than 500 nm, width W1 is less than 100 nm, and advantageously no more than 50-80 nm. Although illustrated with a continuous profile that tapers from width W1 at a top to width W2 at a bottom, trench or via 405 may have a nearly vertical profile, or a bowed profile, etc.

FIG. 4C illustrates capacitor structure 300 following a recess etch of dielectric material layer 402 where some sidewall portions of via or trench 405 are laterally recessed relative to other portions of the sidewall. In the example illustrated, a sidewall portion 411 of dielectric material layer 402 is laterally recessed relative to a sidewall portion 412 of dielectric material layer 401 along the depth D1 of via or trench 405. Lateral recess length L1 may vary with implementation. In exemplary embodiments, length L1 is at least equal to width W1, and advantageously greater than width W1. In some examples, length L1 is at least 150 nm. As noted above, any dry or wet isotropic etch offering suitable selectivity between dielectric material layers 401 and 402 may be practiced to recess sidewall 411 relative to sidewall 412.

FIG. 4D further illustrates capacitor structure 300 following deposition of a MIM material stack comprising a first metal layer 415, a second metal layer 425 and an intervening insulator layer 420. Metal layer 415 and insulator layer 420 conformally follow the laterally recessed sidewalls as continuous serpentine films lining via or trench 405. Metal layer 425 similarly extends into the recesses by approximately the recess length L1, but may only form fins rather than fold-back on itself within the gap remaining. The serpentine films have a surface area augmented by multiples of approximately the recess length L1 that is further a function of the number of recesses dictated by the number of bi-layers. As further illustrated, metal layer 415 is to function as a first capacitor plate coupled to a first voltage rail (e.g., Vdd) while metal layer 425 is to function as a second capacitor plate coupled to a second voltage rail (e.g., Vss). These voltage rails may be implemented with backside metallization (e.g., BV3, as shown in FIG. 3).

Insulator layer 420 has a film thickness T3 that may vary with implementation. In some exemplary embodiments, an insulator layer 420 has a thickness of no more than 20 nm, and may be less than 10 nm (e.g., 1-8 nm). Insulator layer 420 may have any composition known to be a suitable capacitor insulator at the chosen film thickness T3. In some embodiments, insulator layer 420 is a silicon-based dielectric, such as silicon dioxide, silicon nitride, or a silicon oxynitride. In other embodiments, insulator layer 420 is a high-k material having a relative permittivity exceeding that of Si₃N₄, such as HfO₂. The composition of metal layers 415, 425 may each similarly vary with implementation, In some examples, metal layers 415, 425 are both predominantly tungsten, predominantly copper, predominantly ruthenium, or predominantly molybdenum. Metal layers 415, 425 may have any film thickness as a function of the composition of the metal layer and associated electrical resistance, and gap dimensions associated with thickness T1.

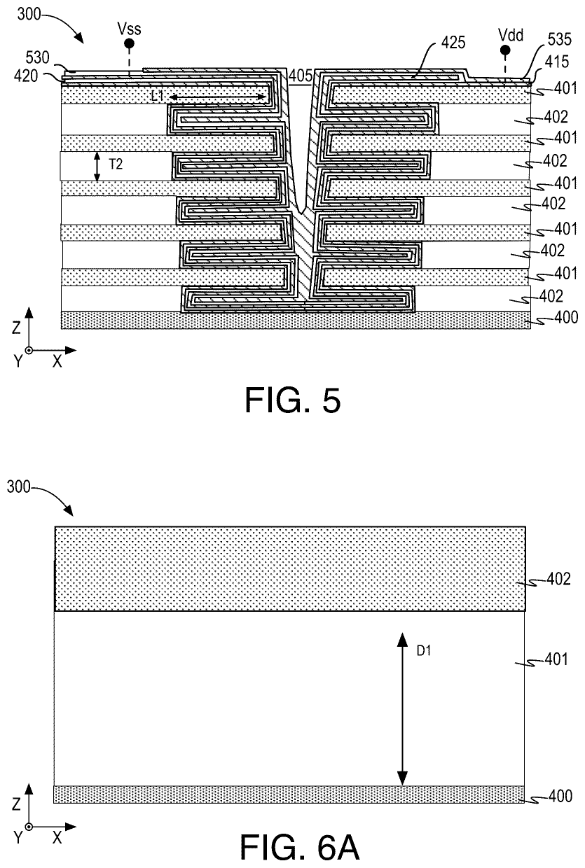

In some embodiments, a high-density capacitor comprises a MIM stack with more than one insulator layer. FIG. 5 illustrates another exemplary embodiment of a high-density capacitor structure 300, which includes an another insulator layer 530 and metal layer 535 in addition to metal layers 415, 425 and intervening insulator layer 420. In this example, sidewalls of dielectric material layer 402 have been recessed from sidewalls of dielectric material 401 by lateral length L1. The greater thickness T2 enables the three metal layer/two insulator layer MIM stack to fold back on itself, forming a stack structure with a serpentine profile that lines the recessed sidewalls of via or trench 405 and undulates between sidewall portions 411 and 412. As further illustrated, metal layers 535 and 415 are connected together at a first voltage rail (e.g., Vdd), while metal layer 425 is connected to a second voltage rail (e.g., Vss). Depending on the thickness T2, a capacitor MIM stack may comprise more insulator layers (e.g., 3, 4, etc.) and more metal layers (e.g., 4, 5, etc.).

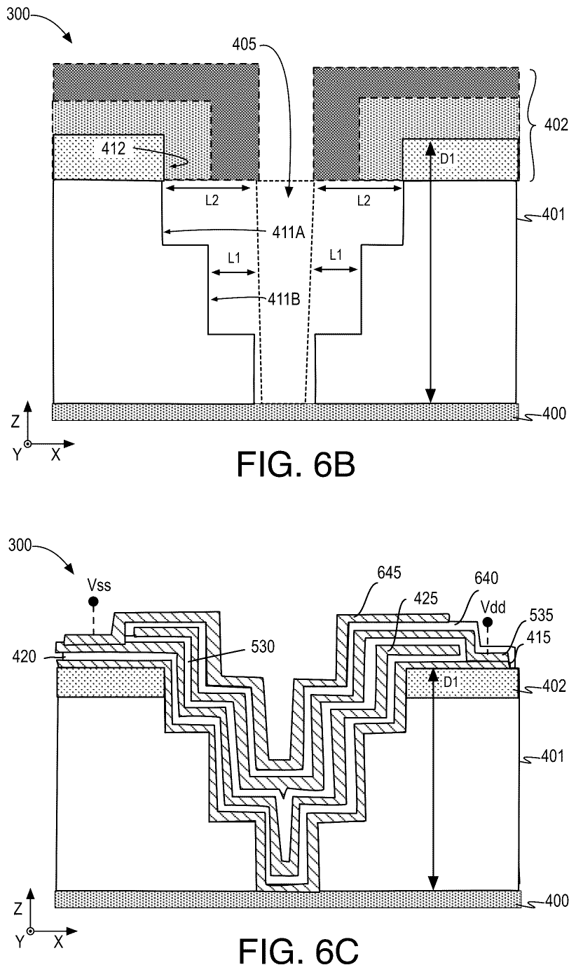

FIG. 6A-6C are cross-sectional views of a high-density capacitor structure evolving as the methods illustrated in FIG. 1 are practiced, in accordance with some alternative embodiments where capacitor density is increased through a staircase structure. For such embodiments, the lateral recess etch at block 140 is performed iteratively between stages of the via or trench etch to introduced lateral jogs or step topography along the depth of the via or trench.

Referring first to FIG. 6A, a high-density capacitor structure 300 again comprises dielectric material layers 401, 402 in a stack over base layer 400. In this example, there is a single bi-layer stack of thickness, or depth exceeding depth D1. Alternatively, high-density capacitor structure 300 may comprise two or more bi-layers, for example substantially as described above for serpentine embodiments.

In FIG. 6B, a via or trench opening is again defined in the bi-layer stack of dielectric materials. However, to reach depth D1, via or trench 405 is etched in multiple discrete stages or steps. Between each stage of the dielectric material etch, dielectric material layer 402 is laterally recessed, for example with an isotropic trim etch suitable for its chemical composition. For some embodiments where dielectric material layers 401 and 402 are both silicon-based compositions with one dielectric material layer comprising more oxygen and the other dielectric material comprising more nitrogen, an isotropic oxide-selective or nitride-selective etch may be performed to laterally recess sidewall 412 of dielectric material layer 402 one or more times during the etch of via or trench 405. In some examples, each recess etch trims sidewall 412 by at least 150 nm.

Following each sidewall recession, dielectric material layer 401 is anisotropically etched with any etch process suitable for the composition of dielectric material layer 401, and as masked by dielectric material layer 402. The anisotropic etch cycles therefore advance a step into dielectric material layer 401 corresponding to each sidewall recession. In FIG. 6B, a reference anisotropic etch profile of via or trench 405 is represented in dashed line to highlight the lateral length L1 that a sidewall portions 411B and 412 are recessed, and lateral length L2 that sidewall portion 411A is recessed, thereby forming a staircase profile with three steps. In the illustrated examples lateral length L2 is approximately twice lateral length L1.

FIG. 6C further illustrates capacitor structure 300 following deposition of a MIM material stack including metal layers 415, 425, 535 and 645 and intervening insulator layers 420, 530, and 640. The MIM stack layers are continuous over staircase profile of the via or trench 405. Each metal layer and each insulator layer may have any of the properties described above in the context of serpentine embodiments. Although four metal layers are illustrated, a capacitor structure may have any number of metal layers (e.g., 5-10), as allowed by the lower effective aspect ratio of the staircase profile.

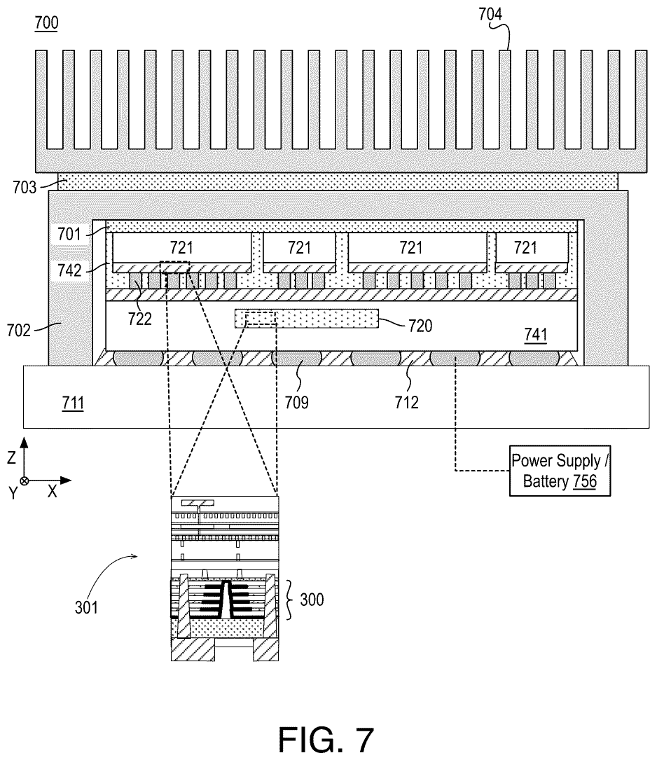

Embodiments of the high-density capacitor structures described above may be employed in a wide range of IC devices and further integrated in a wide range of computer-based applications. FIG. 7 is a cross-sectional view illustrating a microelectronic device assembly including an IC die with an embedded or integrated high-density MIM capacitor structure; in accordance with some embodiments. Microelectronic device assembly 700 includes a plurality of IC dies 721 joined to package substrate 741 with die-level interconnects 722 and optionally embedded in a mold material 742. However, any single IC die, 3D stacked multichip device, multi-chip composite structure, or the like may be similarly assembled within microelectronic device assembly 700.

A thermal interface material (TIM) 701 is between IC dies 721 and a heat spreader and/or lid 702, which extends beyond a perimeter of package substrate 741, and is mounted to board 711. Another TIM 703 is between heat spreader 702 and a thermal dissipation device 704, which may be a heat sink, heat pipe or other thermal solution.

Package substrate 741 is coupled to a board 711 with package-level interconnects 709 (e.g., solder features) that may be at least partially surrounded by underfill material 712. Board 711 may include any suitable substrate such as a motherboard, interposer, or the like. Microelectronic device assembly 700 is coupled to a power supply 756, for example through one or more of board 711 and package substrate 741. Power supply 756 may include a battery and multi-rail power supply circuitry, such as a switching supply with a voltage converter, etc.

Package substrate 741 may comprise one or more insulator layers and routing metallization layers. Insulator layers may be a portion of a package substrate or a build-up layer over or on the package substrate. In some embodiments, package substrate 741 includes an inorganic substrate material, such as glass. For example, package substrate 741 may include a layer of bulk glass, such as any of those described above in the context of substrate 201. In some embodiments, the layer of bulk glass is rectangular in shape in a plan view. However, the bulk glass may have other shapes. In some embodiments, substrate 741 has a thickness in the range of 50 μm to 1.4 mm (i.e., in the z-direction).

As shown in FIG. 7, a passive or active IC die 720 is embedded within package substrate 741. In exemplary embodiments, IC die 720 comprises IC die structure 301 that further includes high-density MIM capacitor structure 300, for example substantially as described elsewhere herein. In other embodiments, at least one of IC die 721 comprises IC die structure 301 that further includes high-density MIM capacitor structure 300, for example substantially as described elsewhere herein.

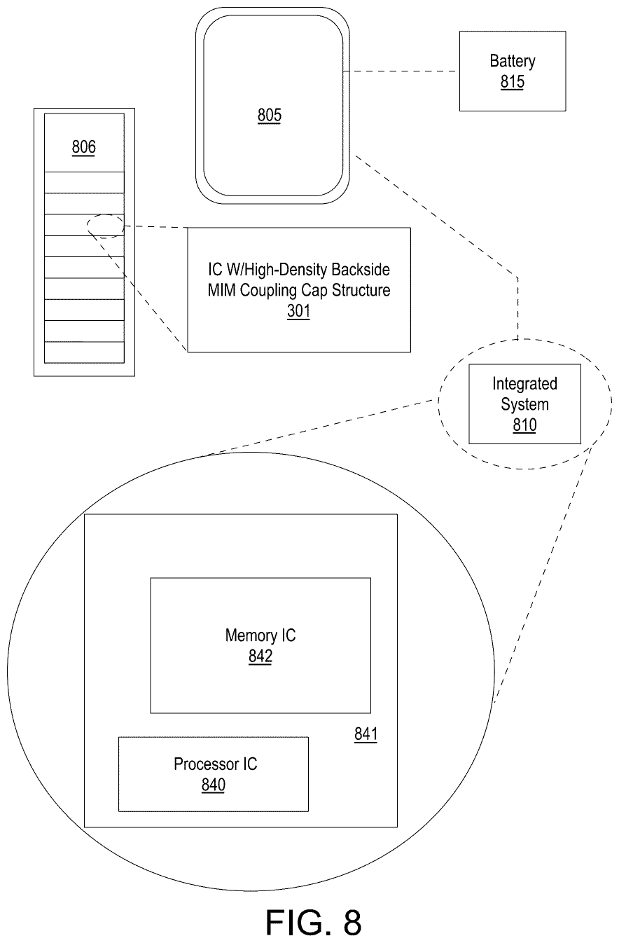

The various MIM capacitor structures, and methods of forming such structures, described herein may be integrated into a wide variety of IC packages and systems that include such IC packages. FIG. 8 illustrates a mobile computing platform 805 and a server machine 806, each employing at least one IC die that includes IC die structure 301 further including high-density MIM capacitor structure 300, for example as described elsewhere herein.

Server machine 806 may be any commercial server, for example including any number of high-performance computing platforms disposed within a rack and networked together for electronic data processing, such as large language model (LLM) processing. The mobile computing platform 805 may be any portable device configured for each of electronic data display, electronic data processing, wireless electronic data transmission, or the like. For example, the mobile computing platform 805 may be any of a tablet, a smart phone, laptop computer, etc., and may include a display screen (e.g., a capacitive, inductive, resistive, or optical touchscreen), an integrated system 810, and a battery 815.

As illustrated in the expanded view of FIG. 8, mobile computing platform 805 comprises an integrated system 810 hosting a package 841 further hosting a processor IC 840 and a memory IC 842. At least one of package 841, processor IC 840 or memory IC 842 includes a high-density MIM capacitor structure 300, for example as described elsewhere herein.

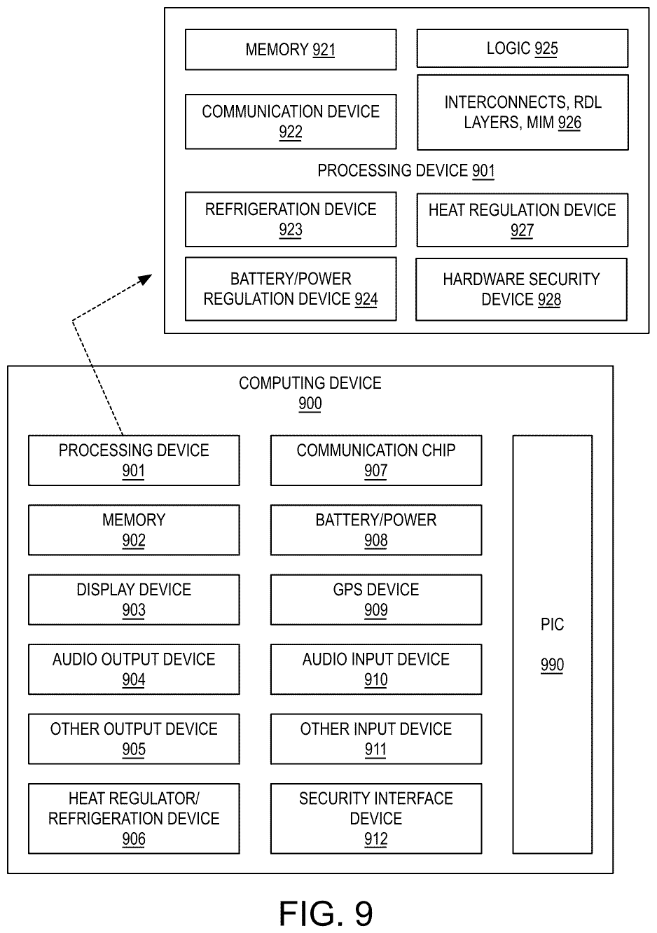

FIG. 9 is a block diagram of a cryogenically cooled computing device 900 in accordance with some embodiments. For example, one or more components of computing device 900 may include an IC die comprising transistor structures and through-substrate capacitor structures that are both contacted by backside metallization, for example as described elsewhere herein. A number of components are illustrated in FIG. 9 as included in computing device 900, but any one or more of these components may be omitted or duplicated, as suitable for the application. In some embodiments, some or all of the components included in computing device 900 may be attached to one or more printed circuit boards (e.g., a motherboard). In some embodiments, various ones of these components may be fabricated onto a single system-on-a-chip (SoC) die. Additionally, in various embodiments, computing device 900 may not include one or more of the components illustrated in FIG. 9, but computing device 900 may include interface circuitry for coupling to the one or more components. For example, computing device 900 may not include a display device 903, but may include display device interface circuitry (e.g., a connector and driver circuitry) to which display device 903 may be coupled.

Computing device 900 may include a processing device 901 (e.g., one or more processing devices). As used herein, the term processing device or processor indicates a device that processes electronic data from registers and/or memory to transform that electronic data into other electronic data that may be stored in registers and/or memory. Processing device 901 may include a memory 921, a communication device 922, a refrigeration/active cooling device 923, a battery/power regulation device 924, logic 925, interconnects 926 (i.e., optionally including redistribution layers (RDL) or metal-insulator-metal (MIM) devices), a heat regulation device 927, and a hardware security device 928.

Processing device 901 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 901 may include a memory 902, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 921 includes memory that shares a die with processing device 901. This memory may be used as cache memory and may include embedded dynamic random-access memory (eDRAM) or spin transfer torque magnetic random-access memory (STT-M RAM).

Computing device 900 may include a heat regulation/refrigeration device 906. Heat regulation/refrigeration device 906 may maintain processing device 901 (and/or other components of computing device 900) at a predetermined low temperature during operation. This predetermined low temperature may be any temperature discussed elsewhere herein.

In some embodiments, computing device 900 may include a communication chip 907 (e.g., one or more communication chips). For example, the communication chip 907 may be configured for managing wireless communications for the transfer of data to and from computing device 900. The term “wireless” and its derivatives may be used to describe circuits, devices, systems, methods, techniques, communications channels, etc., that may communicate data through the use of modulated electromagnetic radiation through a nonsolid medium.

Communication chip 907 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). Communication chip 907 may operate in accordance with other wireless protocols in other embodiments. Computing device 900 may include a photonic IC (PIC) 990 to facilitate optical communications. Communication chip 907 may therefore manage optical (fiber) communications.

Computing device 900 may include battery/power circuitry 908. Battery/power circuitry 908 may include one or more energy storage devices (e.g., batteries or capacitors) and/or circuitry for coupling components of computing device 900 to an energy source separate from computing device 900 (e.g., AC line power).

Computing device 900 may include a display device 903 (or corresponding interface circuitry, as discussed above). Display device 903 may include any visual indicators, such as a heads-up display, a computer monitor, a projector, a touchscreen display, a liquid crystal display (LCD), a light-emitting diode display, or a flat panel display, for example.

Computing device 900 may include an audio output device 904 (or corresponding interface circuitry, as discussed above). Audio output device 904 may include any device that generates an audible indicator, such as speakers, headsets, or earbuds, for example.

Computing device 900 may include an audio input device 910 (or corresponding interface circuitry, as discussed above). Audio input device 910 may include any device that generates a signal representative of a sound, such as microphones, microphone arrays, or digital instruments (e.g., instruments having a musical instrument digital interface (MIDI) output).

Computing device 900 may include a global positioning system (GPS) device 909 (or corresponding interface circuitry, as discussed above). GPS device 909 may be in communication with a satellite-based system and may receive a location of computing device 900, as known in the art.

Computing device 900 may include another output device 905 (or corresponding interface circuitry, as discussed above). Examples include an audio codec, a video codec, a printer, a wired or wireless transmitter for providing information to other devices, or an additional storage device.

Computing device 900 may include another input device 911 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 900 may include a security interface device 912. Security interface device 912 may include any device that provides security measures for computing device 900 such as intrusion detection, biometric validation, security encode or decode, managing access lists, malware detection, or spyware detection. In some examples, security interface device 912 comprises OTP ROM.

Computing device 900, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the disclosure is not limited to the embodiments described above, but can instead be practiced with modification and alteration without departing from the scope of the appended claims. For example, the above embodiments may include specific combinations of features as further provided below.

In first examples, an integrated circuit (IC) device, comprises a device layer comprising a semiconductor material, a first interconnect metallization structure over a frontside of the device layer, and a second interconnect metallization structure over a backside of the device layer. At least one of the first or second interconnect metallization structures comprises a metal-insulator-metal (MIM) capacitor lining a via or trench and having a serpentine or staircase profile.

In second examples, for any of the first examples the second interconnect metallization structure comprises the MIM capacitor, and the MIM capacitor comprises three or more metal layers and two or more intervening insulator layers.

In third examples, for any of the second examples the via or trench extends through a bi-layer of dielectric material, and a first sidewall of the via or trench within a first dielectric material layer of the bi-layer is laterally recessed from a second sidewall of the via or trench within a second dielectric material layer of the bi-layer.

In fourth examples, for any of the third examples the first dielectric material layer comprises silicon and at least one of oxygen and nitrogen, and the second dielectric material layer comprises silicon and at least one of oxygen and nitrogen.

In fifth examples, for any of the third through fourth examples the bi-layer is one of a plurality of bi-layers that includes at least four bi-layers, and the MIM capacitor lining the via or trench has a serpentine profile undulating between the first sidewall and the second sidewall.

In sixth examples, for any of the fifth examples the first dielectric material has a first thickness exceeding a thickness of the second dielectric material layer.

In seventh examples, for any of the sixth examples the first thickness is less than 100 nm.

In eighth examples, for any of the sixth through seventh examples a top of the via or trench has a first width, and the first sidewall is laterally recessed from the second sidewall by more than the first width.

In ninth examples, for any of the eighth examples the first width is less than 100 nm, and the first sidewall is laterally recessed from the second sidewall by at least 150 nm.

In tenth examples, for any of the first through ninth examples the device layer comprises field effect transistors (FETs), the FETs comprise the semiconductor material, and the FETs are powered with a first voltage rail coupled to a first terminal of the MIM capacitor, and a second voltage rail coupled to a second terminal of the MIM capacitor.

In eleventh examples, for any of the first through tenth examples the MIM capacitor lining the via or trench has a staircase profile comprising two or more sidewall portions, a first sidewall portion proximal to a top of the via or trench laterally recessed from a second sidewall portion proximal to a bottom of the via or trench.

In twelfth examples, for any of the eleventh examples the first sidewall portion is laterally recessed from the second sidewall portion by at least 150 nm.

In thirteenth examples, for any of the twelfth examples the via or trench is at least 500 nm in depth between the top of the via or trench and the bottom of the via or trench, the staircase profile comprises at least three sidewall portions between the top of the via or trench and the bottom of the via or trench, and each sidewall portion is laterally recessed from another sidewall portion by at least 150 nm.

In fourteenth examples, for any of the thirteenth examples the second interconnect metallization structure comprises the MIM capacitor, and the MIM capacitor comprises four or more metal layers and three or more intervening insulator layers.

In fifteenth examples, a method comprises depositing at least four bi-layers of dielectric material over a back side of an integrated circuit (IC) die structure comprising a device layer and a frontside interconnect metallization structure on a front side of the device layer. The method comprises etching a via or trench through the bi-layers of dielectric material. The method comprises laterally recessing a first sidewall of a first dielectric material layer within each of the bi-layers relative to a second sidewall of a second dielectric material layer within each of the bi-layers. The method comprises depositing into the via or trench a metal-insulator-metal (MIM) stack comprising at least two metal layers and an intervening insulator layer, the MIM stack having a serpentine profile undulating between each of the first sidewalls and each of the second sidewalls.

In sixteenth examples, for any of the fifteenth examples a first of the metal layers is to be coupled to a first power supply voltage rail and a second of the metal layers is to be coupled to a second power supply voltage rail.

In seventeenth examples, for any of the fifteenth through sixteenth examples etching a via or trench comprises forming an opening of a first width, and laterally recessing the sidewall of the first dielectric material layer relative to the sidewall of the second dielectric material layer comprises recessing at least four layers of the first dielectric material by at lateral length exceeding the first width.

In eighteenth examples a method comprises depositing at least one bi-layer of dielectric material over a back side of an integrated circuit (IC) die structure comprising a device layer and a frontside interconnect metallization structure on a front side of the device layer. The method comprises etching a via or trench through the bi-layer of dielectric material. The etching comprises etching to a first depth a step of a first width, laterally recessing a first sidewall of a first dielectric material layer within the bi-layer relative to a second sidewall of a second dielectric material layer within the bi-layer, and etching to a second depth the step of a first width. The method comprises depositing into the via or trench a metal-insulator-metal (MIM) stack comprising at least three metal layers and two intervening insulator layers, the MIM stack having a staircase profile traversing the first depth and the second depth.

In nineteenth examples, for any of the eighteenth examples the method comprises depositing the MIM stack comprising depositing at least four metal layers.

In twentieth examples, for any of the eighteenth through nineteenth examples laterally recessing a first sidewall relative to a second sidewall comprises recessing the first sidewall by at least 150 nm.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosure should, therefore, be determined with reference to the appended claims, along with the full scope of equivalents to which such claims are entitled.

What is claimed is:

1. An integrated circuit (IC) device, comprising:
a device layer comprising a semiconductor material;
a first interconnect metallization structure over a frontside of the device layer; and
a second interconnect metallization structure over a backside of the device layer, wherein at least one of the first or second interconnect metallization structures comprises a metal-insulator-metal (MIM) capacitor lining a via or trench and having a serpentine or staircase profile.

2. The IC device of claim 1, wherein:
the second interconnect metallization structure comprises the MIM capacitor; and
the MIM capacitor comprises three or more metal layers and two or more intervening insulator layers.

3. The IC device of claim 2, wherein:
the via or trench extends through a bi-layer of dielectric material; and
a first sidewall of the via or trench within a first dielectric material layer of the bi-layer is laterally recessed from a second sidewall of the via or trench within a second dielectric material layer of the bi-layer.

4. The IC device of claim 3, wherein:
the first dielectric material layer comprises silicon and at least one of oxygen and nitrogen; and
the second dielectric material layer comprises silicon and at least one of oxygen and nitrogen.

5. The IC device of claim 3, wherein:
the bi-layer is one of a plurality of bi-layers that includes at least four bi-layers; and
the MIM capacitor lining the via or trench has a serpentine profile undulating between the first sidewall and the second sidewall.

6. The IC device of claim 5, wherein the first dielectric material has a first thickness exceeding a thickness of the second dielectric material layer.

7. The IC device of claim 6, wherein the first thickness is less than 100 nm.

8. The IC device of claim 6, wherein:
a top of the via or trench has a first width; and
the first sidewall is laterally recessed from the second sidewall by more than the first width.

9. The IC device of claim 8, wherein:
the first width is less than 100 nm; and
the first sidewall is laterally recessed from the second sidewall by at least 150 nm.

10. The IC device of claim 1, wherein:
the device layer comprises field effect transistors (FETs);
the FETs comprise the semiconductor material; and
the FETs are powered with a first voltage rail coupled to a first terminal of the MIM capacitor, and a second voltage rail coupled to a second terminal of the MIM capacitor.

11. The IC device of claim 1, wherein:
the MIM capacitor lining the via or trench has a staircase profile comprising two or more sidewall portions, a first sidewall portion proximal to a top of the via or trench laterally recessed from a second sidewall portion proximal to a bottom of the via or trench.

12. The IC device of claim 11, wherein the first sidewall portion is laterally recessed from the second sidewall portion by at least 150 nm.

13. The IC device of claim 11, wherein:
the via or trench is at least 500 nm in depth between the top of the via or trench and the bottom of the via or trench;
the staircase profile comprises at least three sidewall portions between the top of the via or trench and the bottom of the via or trench; and
each sidewall portion is laterally recessed from another sidewall portion by at least 150 nm.

14. The IC device of claim 13, wherein:
the second interconnect metallization structure comprises the MIM capacitor; and
the MIM capacitor comprises four or more metal layers and three or more intervening insulator layers.

15. A method, comprising:
depositing at least four bi-layers of dielectric material over a back side of an integrated circuit (IC) die structure comprising a device layer and a frontside interconnect metallization structure on a front side of the device layer;
etching a via or trench through the bi-layers of dielectric material;
laterally recessing a first sidewall of a first dielectric material layer within each of the bi-layers relative to a second sidewall of a second dielectric material layer within each of the bi-layers; and
depositing into the via or trench a metal-insulator-metal (MIM) stack comprising at least two metal layers and an intervening insulator layer, the MIM stack having a serpentine profile undulating between each of the first sidewalls and each of the second sidewalls.

16. The method of claim 15, wherein a first of the metal layers is to be coupled to a first power supply voltage rail and a second of the metal layers is to be coupled to a second power supply voltage rail.

17. The method of claim 15, wherein:
etching a via or trench comprises forming an opening of a first width; and
laterally recessing the sidewall of the first dielectric material layer relative to the sidewall of the second dielectric material layer comprises recessing at least four layers of the first dielectric material by at lateral length exceeding the first width.

18. A method comprising:
depositing at least one bi-layer of dielectric material over a back side of an integrated circuit (IC) die structure comprising a device layer and a frontside interconnect metallization structure on a front side of the device layer;
etching a via or trench through the bi-layer of dielectric material, wherein the etching comprises:
etching to a first depth a step of a first width;
laterally recessing a first sidewall of a first dielectric material layer within the bi-layer relative to a second sidewall of a second dielectric material layer within the bi-layer; and
etching to a second depth the step of a first width; and
depositing into the via or trench a metal-insulator-metal (MIM) stack comprising at least three metal layers and two intervening insulator layers, the MIM stack having a staircase profile traversing the first depth and the second depth.

19. The method of claim 18, wherein depositing the MIM stack comprising depositing at least four metal layers.

20. The method of claim 18, wherein laterally recessing a first sidewall relative to a second sidewall comprises recessing the first sidewall by at least 150 nm.
